(19) United States
(12) Patent Application Publication
(10) Pub. No.: US 2006/0273437 A1
(43) Pub. Date: Dec. 7, 2006

(54) Optoelectronic semiconductor assembly with an optically transparent cover, and a method for producing optoelectronic semiconductor assembly with an optically transparent cover

(76) Inventors: Gottfried Beer, Nittendorf (DE); Markus Brunnbauer, Lappersdorf (DE); Edward Fuergut, Dasing (DE)

Correspondence Address: EDELL, SHAPIRO & FINNAN, LLC, 1901 RESEARCH BLVD., SUITE 400, ROCKVILLE, MD, 20850, US

(21) Appl. No.: 11/437,826

(22) Filed: May 22, 2006

(30) Foreign Application Priority Data
May 20, 2005 (DE) 10 2005 023 947.1

(51) Int. Cl. H01L 23/02

(52) U.S. Cl. 257/680

(57) ABSTRACT

An optoelectronic semiconductor assembly includes at least the following components: a semiconductor chip with an optical sensor region on its active topside, a wiring substrate on which the semiconductor chip is arranged, electrical connecting elements extending between the semiconductor chip and the wiring substrate, and an optically transparent cover an optically transparent plastic encapsulation compound that embeds at least the semiconductor chip and electrical connecting elements. The optically transparent encapsulation compound can be formed via a compression molding process.

### CROSS REFERENCE TO RELATED APPLICATIONS

This application claims priority under 35 USC §119 to German Application No. DE 10 2005 023 947.1, filed on May 20, 2005, and titled “Optoelectronic Semiconductor Assembly with an Optically Transparent Cover, and Method for Producing the Same,” the entire contents of which are hereby incorporated by reference.

### FIELD OF THE INVENTION

The invention relates to an optoelectronic semiconductor assembly with an optically transparent cover.

### BACKGROUND

An optoelectronic semiconductor assembly, which is described in German Patent Application DE 103 46 474.3, includes components of the semiconductor assembly that are embedded in a non-transparent plastic compound except for the sensor region of the semiconductor chip. The sensor region is protected by an optically transparent cover. This optoelectronic semiconductor assembly has the disadvantage that its production is expensive, the more so as the plastic encapsulation compound and the transparent cover have to be produced in two separate method steps.

The application of such an optically transparent cover by dispensing disadvantageously requires a preformed housing in the form of the plastic encapsulation compound with a depression in which the sensor region is exposed such that the transparent cover can be introduced into the depression.

Other methods for providing the components of an optoelectronic semiconductor assembly with a transparent cover on a carrier operate by transfer molding an individual cavity of a casting mold. This has the disadvantage of a low assembly density on the carrier. Sealing the casting mold off from the carrier is problematic in this case. Additionally, instances of contamination of the casting mold influence the functioning of the optoelectronic assembly.

Simultaneous transfer molding of a number of cavities is disadvantageously restricted to a limited number of assemblies. The selection of materials is also limited, since pastes or silicones cannot be used in transfer molding. The disadvantages mentioned above, such as sealing problems at the casting mold and contamination problems, are also not solved in the case of simultaneous transfer molding of a number of cavities.

### SUMMARY

The present invention provides an optoelectronic assembly and a method for producing an optelectronic assembly in which the abovenamed disadvantages are overcome. The optoelectronic assembly is also produced cost-effectively and by mass production in accordance with the invention.

In accordance with the invention, an optoelectronic semiconductor assembly with an optically transparent cover is provided, comprising a semiconductor chip including an optical sensor region on its active topside, and a wiring substrate on which the semiconductor chip is arranged. Moreover, the optoelectronic semiconductor assembly comprises connecting elements as components between the semiconductor chip and the wiring substrate. The optoelectronic semiconductor assembly according to the invention includes as an optically transparent cover an optically transparent plastic encapsulation compound embedding the components.

The semiconductor assembly of the invention provides at least one advantage that it is possible to dispense entirely with a non-transparent plastic encapsulation compound which has, for example, surrounding depressions for a transparent cover. On the contrary, this plastic encapsulation compound including the transparent cover over the sensor region of an optoelectronic assembly is advantageously replaced by a complete, optically transparent plastic encapsulation compound. The advantage of cost effective production is associated therewith, because the transfer molding of a non-transparent plastic encapsulation compound is completely dispensed with. Moreover, it is possible to dispense with providing or digging depressions in the plastic encapsulation compound in order to expose the sensor region of a semiconductor chip. Finally, it is likewise possible to dispense with covering this sensor region with a transparent plastic compound since, after all, the entire plastic encapsulation compound is transparent, and the components such as the wiring substrate, the semiconductor chips and the connecting elements are embedded in a transparent overall compound.

A further advantage of such semiconductor assemblies is that they need not be compression molded, but that they can be produced on a large panel on which a layer of transparent plastic encapsulation compound embeds the components on the topside of the wiring substrate or carrier completely by compression molding. Separating such a panel composed of a carrier plate, the semiconductor chips in the corresponding semiconductor positions, and the transparent plastic encapsulation compound as uppermost layer into individual optoelectronic semiconductor assemblies can be carried out with the aid of relatively simple and known techniques. It is characteristic that the peripheral sides of these semiconductor assemblies include a transparent upper region made from an optically transparent plastic encapsulation compound, and a non-transparent lower peripheral region made from the wiring substrate material. This peripheral side structure is also unknown for optoelectronic semiconductor assemblies of conventional design.

The optically transparent plastic encapsulation compound preferably includes a cured transparent silicone compound. Such silicone compounds can be applied using compression molding over a large area of appropriately prepared carriers with the aid of appropriate semiconductor chips and connecting elements. On the other hand, it is also possible for the optically transparent plastic encapsulation compound to include an acrylic compound, such acrylic resins being capable of curing to form transparent plastic encapsulation layers, and in this case embed in a transparent acrylic plate the silicone chips, together with their bonded connections, arranged on the topside of the wiring substrate in the individual semiconductor assembly positions.

In a further embodiment of the invention, the optoelectronic semiconductor assembly includes on its topside the optically transparent plastic encapsulation compound which seals the semiconductor chip and the topside of the wiring substrate, external contacts of the semiconductor assembly being arranged on the underside thereof, which is simultaneously the underside of the wiring substrate. Such an optoelectronic semiconductor assembly has the advantage that it can be surface mounted, and that it is therefore possible to mount it in a very small space of a primary printed circuit board.

In a further embodiment of the invention, the optoelectronic semiconductor assembly includes on the transparent plastic encapsulation compound a transparent film which includes optical structures. Such a film can be produced simultaneously for a multiplicity of semiconductor assembly positions arranged in rows and in columns, and be applied to the flat topside of a panel composed of a wiring substrate with applied semiconductor chips and applied optically transparent plastic encapsulation compound. In this case, the optical structures on the topside of the transparent plastic encapsulation compound are aligned in such a way that they are aligned with the respectively corresponding sensor regions of semiconductor chips.

In a preferred embodiment of the invention, the optical structures include Fresnel lenses, which are arranged opposite the sensor regions of the semiconductor chips. To this end, the Fresnel lenses are impressed into the topside of the film and comprise annular structures which act as positive lenses such that the light can be focused onto the sensor regions of the semiconductor chips.

A method for producing an optoelectronic semiconductor assembly with an optically transparent cover includes the following steps. First, a wiring substrate with a multiplicity of semiconductor assembly positions is produced. Subsequently, the wiring substrate is fitted with semiconductor chips which have an optical sensor region. Subsequently, the wiring substrate is connected electrically to the semiconductor chips via electrical connecting elements in the respective semiconductor assembly positions. Thereafter, an optically transparent plastic encapsulation compound is applied by compression molding while embedding the wiring substrate, the semiconductor chips and the connecting elements in that optically transparent plastic encapsulation compound. After the curing of the optically transparent plastic encapsulation compound, the substrate with applied transparent plastic encapsulation compound is separated into individual optoelectronic semiconductor components with an optically transparent plastic encapsulation compound as transparent cover.

This method includes an advantage of producing a composite sheet which has a transparent layer made from a plastic encapsulation compound, and a carrier in the form of a wiring substrate. The transparent plastic encapsulation compound can comprise an acrylic resin, two resin components being cross-linked with one another in such a way as to produce a transparent, firm composite sheet which can be separated by sawing and is also termed a panel and which includes a plurality of semiconductor assemblies. The surface is smoothed in this case simply by applying a gas pressure, which can also be an underpressure in the case of the acrylic resin, in order to avoid the formation of bubbles in the acrylic glass coating or in the embedding transparent plastic encapsulation compound made from acrylic glass.

It is also possible to apply as transparent plastic encapsulation compound a silicone compound in the case of which a composite sheet in the form of a panel is produced by appropriate compressive pressure, the compressive pressure being exerted by an inert gas on the topside of the transparent plastic encapsulation compound, in order to achieve a surface which is as smooth and glossy as possible.

In a preferred embodiment of the invention, the semiconductor chips with the optical sensor regions on their active topsides are arranged on the wiring substrate in such a way that their rear sides are fixed on the wiring substrate. This has the advantage that, for example, contact surfaces on the semiconductor chip are freely accessible and can be connected via bonding wires to the wiring substrate before being embedded in a transparent plastic encapsulation compound.

In order to connect the wiring substrate electrically to semiconductor chips, bonding wires are bonded onto appropriately provided contact surfaces on the semiconductor chip and onto contact terminal areas on the wiring substrate. Before the separation of the wiring substrate with the transparent plastic encapsulation compound located thereon into individual semiconductor assemblies, it is already possible to apply external contacts to the underside of the wiring substrate, which is simultaneously the underside of the semiconductor assembly.

The separation of the semiconductor assembly positions to form individual optoelectronic semiconductor assemblies can be performed, for example, with the aid of laser removal techniques, of sawing techniques, or of cutting techniques. The cutting techniques are usually punching techniques, the punching dies being designed such that the composite sheet or the panel loses as little material as possible. These separating techniques lend the semiconductor assembly produced its characteristic cuboidal shape. Further working steps are required if, in turn, the edges of the transparent coating are to be chamfered.

Before the separation of the wiring substrate with applied transparent plastic encapsulation compound, it is further advantageous to carry out a method step in which the appropriate external contacts are applied to the underside of the wiring substrate. If these external contacts comprise solder traces the application constitutes surface mounting.

Furthermore, before the panel is separated from a substrate and a transparent plastic encapsulation compound it is further possible to apply thereto a film into which optical structures are impressed. In particular, it is possible to introduce effective Fresnel lenses into the plastic film, since these Fresnel lenses consist of concentric rings and simulate a positive lens. The mode of operation of the sensor region can be further enhanced with the aid of the Fresnel lenses, which are arranged opposite the sensor region of the plastic encapsulation compound.

In summary, sheathing the semiconductor assemblies by applying compression molding to an optically transparent plastic encapsulation compound includes, without limitation, the following advantages:
1. It is possible to use pastes and silicones;
2. it is feasible to produce a relatively large or even arbitrarily large panel;
3. it is likewise advantageously possible to use rewiring via a wiring substrate in this method; and
4. it is possible to integrate Fresnel lenses by using structured films.

The invention thus offers a cost effective production of optoelectronic assemblies by the novel sheathing of the semiconductor chip and the wiring substrate with the aid of a layer made from a transparent plastic encapsulation compound.

The above and still further features and advantages of the present invention will become apparent upon consideration of the following detailed description of specific embodiments thereof, particularly when taken in conjunction with the accompanying drawings wherein like reference numerals in the various figures are utilized to designate like components.

### BRIEF DESCRIPTION OF THE DRAWINGS

FIG. 1 depicts a cross-section through an optoelectronic semiconductor assembly in accordance with a first embodiment of the invention.

FIGS. 2-6 depict method steps for producing the optoelectronic semiconductor assembly of FIG. 1, where FIG. 2 depicts a cross-section through a wiring substrate with a number of semiconductor assembly positions and semiconductor chips which are fixed in the semiconductor assembly positions; FIG. 3 depicts a top view in plan of the wiring substrate of FIG. 2 after application of electrical connecting elements; FIG. 4 depicts a cross-section through the wiring substrate with semiconductor chips of FIG. 3 after application of a transparent plastic encapsulation compound; FIG. 5 depicts a cross-section through the wiring substrate of FIG. 4 after attachment of external contacts; and FIG. 6 depicts a cross-section through an individual semiconductor assembly in accordance with the first embodiment of the invention.

FIGS. 7-9 depict method steps for producing a semiconductor assembly in accordance with a second embodiment of the invention, where FIG. 7 depicts a cross-section through a panel with a number of semiconductor assembly positions, a transparent plastic encapsulation compound embedding components of optoelectronic assemblies in a number of semiconductor assembly positions, and a transparent film being arranged on the topside of the optically transparent plastic encapsulation compound; FIG. 8 depicts a cross-section through the panel of FIG. 7 after attachment of external contact; and FIG. 9 depicts a cross-section through a semiconductor assembly in accordance with the second embodiment of the invention.

### DETAILED DESCRIPTION

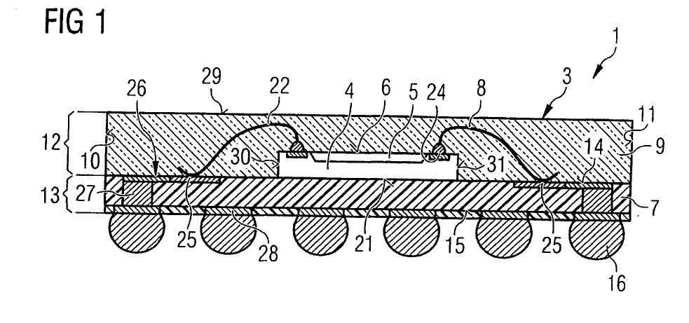

FIG. 1 shows a diagrammatic cross-section through an optoelectronic semiconductor assembly 1 in accordance with a first embodiment of the invention. The optoelectronic semiconductor assembly 1 includes at least one semiconductor chip 4 with an optical sensor region 5 on its active topside 6. The semiconductor chip 5 is arranged with its rear side 21 on a wiring substrate 7, electrical connecting elements 8 electrically connecting contact surfaces 24 on the topside 6 of the semiconductor chip 4 to the contact terminal areas 25 on the topside 14 of the wiring substrate 7 via bonding wires 22. Arranged on the topside 14 of the wiring substrate 7 is a wiring structure 26 which connects the contact terminal areas 25 to contact vias 27 through the wiring substrate 7, the contact vias 27 being electrically connected to the external contact surfaces 28, which carry external contacts 16.

The connecting elements 8, the semiconductor chip 4 and the topside 14 of the wiring substrate 7 are embedded in an optically transparent plastic encapsulation compound 9 which forms a flat topside 29 which simultaneously constitutes the topside of the semiconductor assembly 1 in this first embodiment of the invention. Unlike conventional semiconductor assemblies, the optoelectronic semiconductor assembly 1 includes no opaque plastic encapsulation compound. Rather, the opaque plastic encapsulation compound is completely replaced by an optically transparent plastic encapsulation compound 9. In addition to optimum optical coupling between the optoelectronic sensor region 5 of the semiconductor assembly 4 and the environment, this has the advantage that all the components of the semiconductor assembly can be optically tested such that damage to the bonded connections on the contact surfaces 24 or on the contact terminal areas 25 is rendered directly visible.

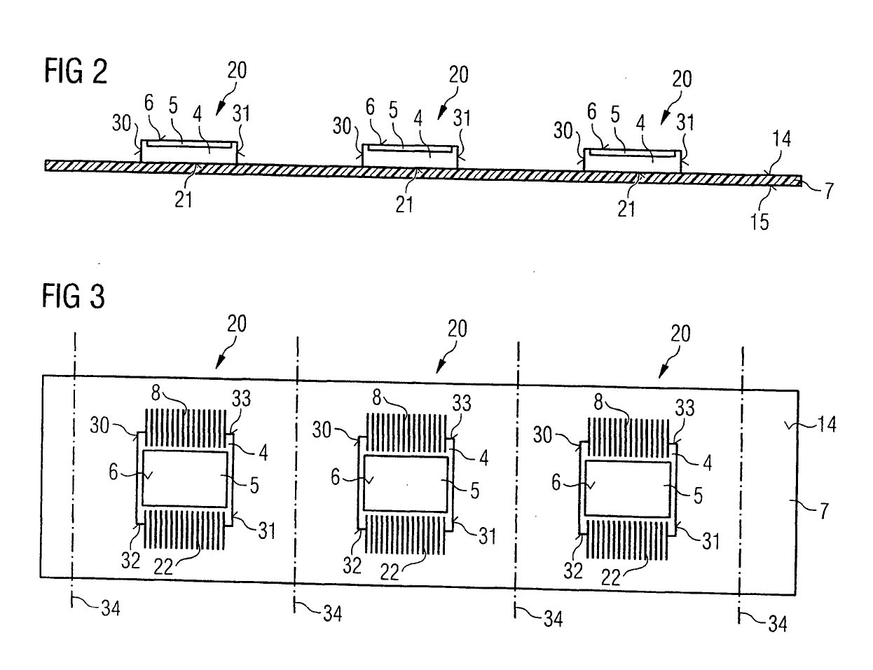

FIGS. 2-6 schematically show production steps for producing the optoelectronic semiconductor assembly 1 of FIG. 1. Components whose function is the same as those in FIG. 1 are marked with the same reference numerals and are not specifically explained in FIGS. 2-6.

FIG. 2 shows a cross-section through a wiring substrate 7 with a number of semiconductor assembly positions 20 and semiconductor chips 4 which are fixed in the semiconductor assembly positions 20. The active topside 6 of the semiconductor chips 4 with the sensor region 5 is freely accessible, while the rear sides 21 of the semiconductor chips 4 are fixed on the topside 14 of the wiring substrate 7.

FIG. 3 shows a plan view of the wiring substrate 7 of FIG. 2 after application of electrical connecting elements 8 between the wiring substrate 7 and the topside 6 of the semiconductor chips 4. In this specific embodiment of the invention, the peripheral sides 30 and 31 of the semiconductor chip 4 are kept free from bonding wires 22, while appropriate bonding wires 22 extend over the peripheral sides 32 and 33 between contact surfaces of the semiconductor chip 4 and contact terminal areas of the wiring substrate 7.

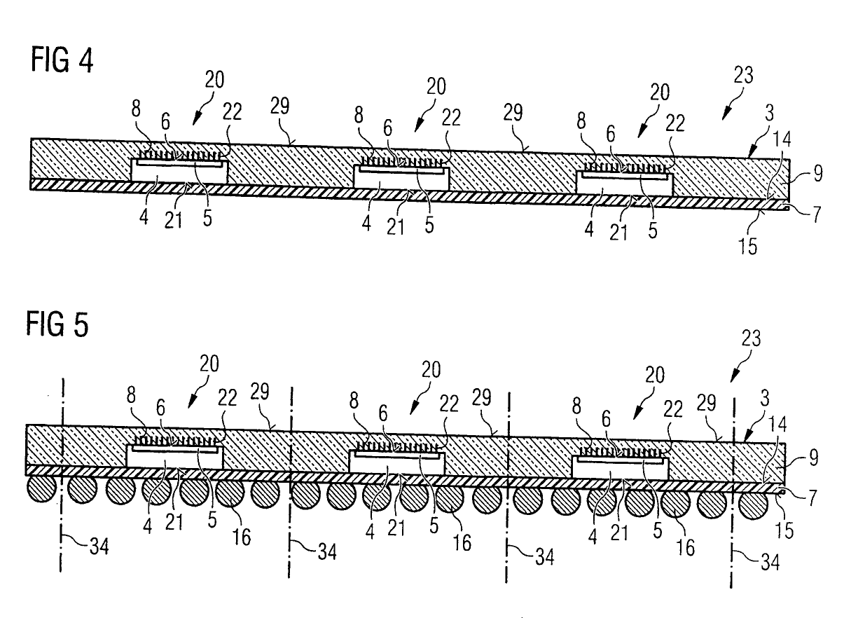

FIG. 4 shows a cross-section through the wiring substrate 7 with semiconductor chips 4 of FIG. 3 after application of a transparent plastic encapsulation compound 9. When the plastic encapsulation compound 9 is being applied, the semiconductor chips 4 and the electrical connecting elements 8 between the semiconductor chip 4 and wiring substrate 7 become completely embedded in the transparent plastic encapsulation compound 9. This embedding can be performed under a reduced pressure by compression molding of an acrylic resin, in the presence of reduced pressure of a surrounding inert gas to release gas bubbles from the acrylic resin, and to apply an acceptable transparent plastic encapsulation compound 9 to the wiring substrate 7. Alternatively, it is also possible to carry out the compression molding in the presence of increased pressure if, for example, a silicone material is used as transparent plastic encapsulation material.

FIG. 5 shows a diagrammatic cross-section through the wiring substrate 7 of FIG. 4 after attachment of external contacts 16 on the underside 15 of the wiring substrate 7. Here, the dashed and dotted lines 34 show the boundaries of the semiconductor assemblies in the individual semiconductor assembly positions 20. The wiring substrate 7 with the optically transparent plastic encapsulation compound 9 is now separated into individual semiconductor assemblies 1 along these boundary lines 34.

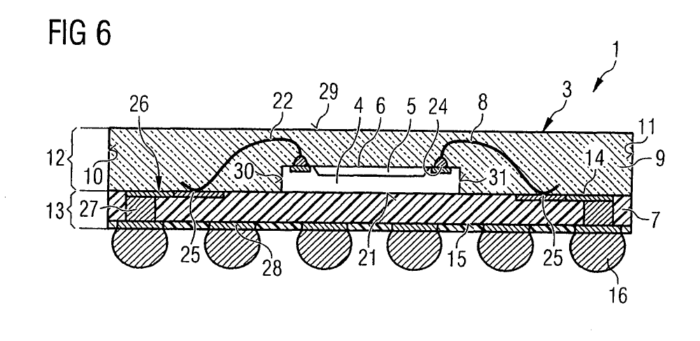

FIG. 6 shows a diagrammatic cross-section through an individual semiconductor assembly 1 in accordance with the first embodiment of the invention. An upper transparent peripheral region 12 and a lower non transparent peripheral region 13 can be seen on the peripheral sides 10 and 11 of the assembly. The upper transparent peripheral region 12 is produced by the separation of the optically transparent plastic encapsulation compound 9 embedding the components of the semiconductor assembly, and the non transparent peripheral region 13 is formed upon the separation of the wiring substrate 7.

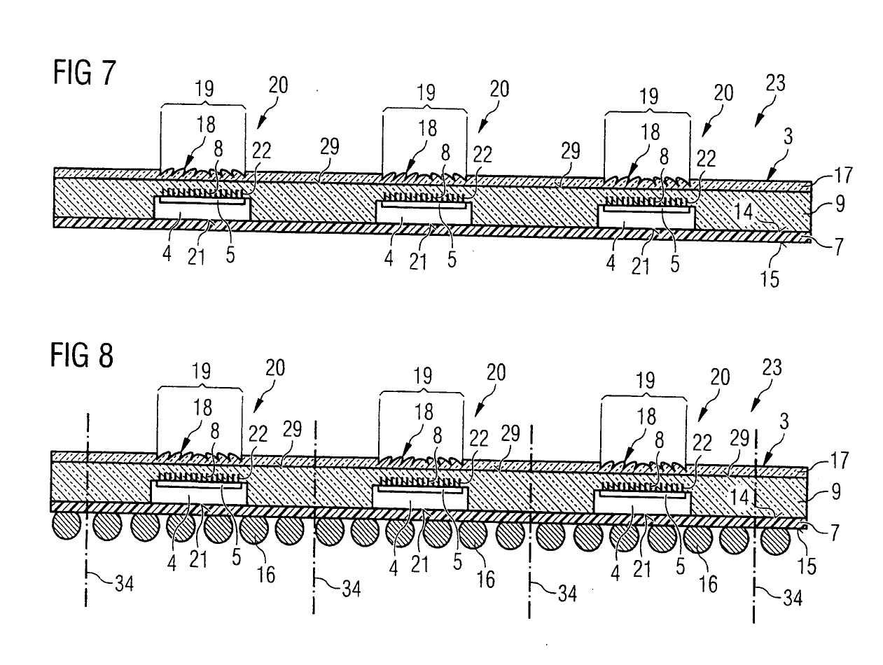

FIGS. 7-9 show additional method steps for producing an optoelectronic semiconductor assembly 2 of a second embodiment of the invention. In particular, FIG. 7 shows a diagrammatic cross-section through a panel 23 with a number of semiconductor assembly positions 20, a transparent plastic encapsulation compound 9 embedding components of optoelectronic assemblies in a number of semiconductor assembly positions 20. In order to produce a semiconductor assembly 2 of a second embodiment of the invention, a transparent plastic film 17 is applied to the flat topside 29 of the transparent plastic encapsulation housing 9 as additional optically transparent cover 3 into which the optical structures 18 are impressed. In this second embodiment of the invention, the impressed optical structures 18 are so-called Fresnel lenses 19 which constitute annular structures in the transparent film 17 and act as positive lenses. These Fresnel lenses 19 are arranged over the sensor regions 5 of the semiconductor chips 4 and focus the light onto the sensor regions 5 of the semiconductor chips 4.

FIG. 8 shows a cross-section through the panel 23 of FIG. 7 after application of external contacts 16 to the underside 15 of the wiring substrate 7. This panel 23 can now be separated into individual optoelectronic semiconductor assemblies of the second embodiment of the invention along the dashed and dotted lines 34.

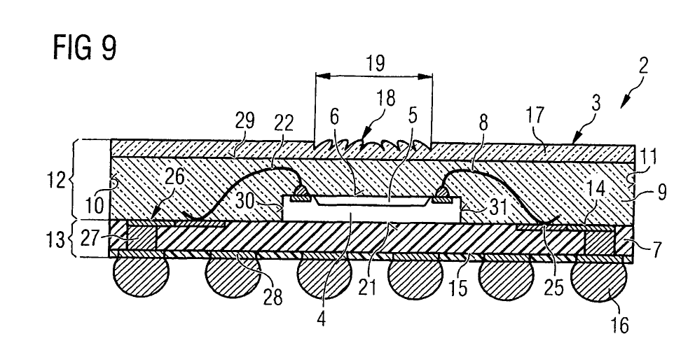

FIG. 9 shows a cross-section through a semiconductor assembly 2 in accordance with the second embodiment of the invention. Seen from the peripheral sides 11 and 12 of the semiconductor assembly 2, this semiconductor assembly 2 includes a transparent region 12 and a non-transparent region 13, where the transparent region 12 is enlarged by a transparent film 17 with an optical structure 18 which constitutes a Fresnel lens 12 in this embodiment. Otherwise, the semiconductor assembly 2 of the second embodiment of the invention corresponds to the semiconductor assembly shown in FIG. 1 of the first embodiment of the invention.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

List of Reference Symbols

1 Optoelectronic semiconductor assembly (1^{st} embodiment)

2 Optoelectronic semiconductor assembly (2^{nd} embodiment)

3 Optically transparent cover

4 Semiconductor chip

5 Optical sensor region

6 Active topside of the semiconductor chip

7 Wiring substrate

8 Electrical connecting element

9 Optically transparent plastic encapsulation compound

10 Peripheral side of the semiconductor assembly

11 Peripheral side of the semiconductor assembly

12 Transparent peripheral region

13 Non-transparent peripheral region

14 Topside of the wiring substrate

15 Underside of the wiring substrate

16 External contact

17 Transparent film

18 Optical structure

19 Fresnel lens

20 Semiconductor component position

21 Rear side of the semiconductor chip

22 Bonding wire

23 Panel

24 Contact surface

25 Contact terminal area

26 Wiring structure

27 Contact via

28 External contact surface

29 Topside of the plastic encapsulation compound

30 Peripheral side of the semiconductor chip

31 Peripheral side of the semiconductor chip

32 Peripheral side of the semiconductor chip

33 Peripheral side of the semiconductor chip

34 Dashed and dotted line

What is claimed:

1. An optoelectronic semiconductor assembly comprising:
a semiconductor chip including an optical sensor region on an active topside of the semiconductor chip;
a wiring substrate including a top side on which the semiconductor chip is disposed;
electrical connecting elements extending between the semiconductor chip and the wiring substrate; and
an optically transparent cover comprising an optically transparent plastic encapsulation compound that embeds at least the semiconductor chip and the electrical connecting elements.

2. The optoelectronic semiconductor assembly of claim 1, wherein the optically transparent plastic encapsulation compound comprises a cured transparent silicone compound.

3. The optoelectronic semiconductor assembly of claim 1, wherein peripheral sides of the semiconductor assembly comprise a transparent peripheral region formed from the optically transparent plastic encapsulation compound and a non-transparent peripheral region formed from from the wiring substrate.

4. The optoelectronic semiconductor assembly of claim 1, wherein the optically transparent plastic encapsulation compound and the semiconductor chip are disposed on the topside of the wire substrate, and external contacts are disposed on an underside of the wire substrate.

5. The optoelectronic semiconductor assembly of claim 1, further comprising a transparent film disposed on the transparent plastic encapsulation compound, wherein the transparent film includes optical structures.

6. The optoelectronic semiconductor assembly of claim 5, wherein the optical structures of the transparent film include a Fresnel lens that focuses optical beams onto the optical sensor region of the semiconductor chip.

7. A method for producing an optoelectronic semiconductor assembly including an optically transparent cover, the method comprising:
producing a wiring substrate with a plurality of semiconductor chip positions along the wiring substrate;
fitting the wiring substrate with semiconductor chips, each semiconductor substrate including an optical sensor region on an active topside of the semiconductor substrate, and electrically connecting the wiring substrate to each semiconductor chip via electrical connecting elements disposed at the semiconductor assembly positions;
applying an optically transparent plastic encapsulation compound by compression molding so as to embed the wiring substrate with semiconductor chips and connecting elements in the optically transparent plastic encapsulation compound;
curing the optically transparent plastic encapsulation compound; and
separating the wiring substrate into individual optoelectronic semiconductor assemblies, wherein each optoelectronic semiconductor assembly includes an optically transparent plastic encapsulation compound as a transparent cover.

8. The method of claim 7, wherein the semiconductor chips with optical sensor regions on the active topsides of the semiconductor ships are arranged such that a rear side of each semiconductor chip engages the wiring substrate.

9. The method of claim 7, wherein bonding wires are bonded between contact surfaces of each semiconductor chip and contact terminal areas of the wiring substrate so as to electrically connect the wiring substrate to the semiconductor chips.

10. The method of claim 7, wherein the wiring substrate is separated into individual optoelectronic semiconductor assemblies via a laser removal technique.

11. The method of claim 7, wherein the wiring substrate is separated into individual optoelectronic semiconductor assemblies via a sawing technique.

12. The method of claim 7, wherein the wiring substrate is separated into individual optoelectronic semiconductor assemblies via a cutting technique.

13. The method of claim 7, wherein an underside of the wiring substrate is fitted with external contacts before the separation of the wiring substrate into individual optoelectronic semiconductor assemblies.

14. The method of claim 7, wherein a transparent film with optical structures is applied to the transparent plastic encapsulation compound before the separation of the wiring substrate into individual optoelectronic semiconductor assemblies.

15. The method of claim 14, wherein the transparent film includes Fresnel lenses that focus optical beams onto the optical sensor regions of the semiconductor chips.
